(19) United States
(12) Patent Application Publication
(10) Pub. No.: US 2010/0189532 A1
(43) Pub. Date: Jul. 29, 2010

(54) INLINE-TYPE WAFER CONVEYANCE DEVICE

(75) Inventors: Naoki Watanabe, Kawasaki-shi (JP); Einstein Noel Abarra, Tokyo (JP); David Djulianto Djayaprawira, Tokyo (JP); Yasumi Kurematsu, Tokyo (JP)

Correspondence Address: FITZPATRICK CELLA HARPER & SCINTO, 1290 Avenue of the Americas, NEW YORK, NY, 10104-3800, US

(73) Assignee: CANON ANELVA CORPORATION, Kawasaki-shi (JP)

(21) Appl. No.: 12/720,372

(22) Filed: Mar. 9, 2010

Related U.S. Application Data
(63) Continuation of application No. PCT/JP2007/071815, filed on Nov. 9, 2007.

(51) Int. Cl. H01L 21/677

(52) U.S. Cl. 414/217; 414/805

(57) ABSTRACT

A structure is provided in which a load lock chamber (51) for carrying in and out a wafer, a first conveyance module (53a) having a first conveyance mechanism (54a), a first process module (52a), a second conveyance module (53b) having a second conveyance mechanism (54b), and a second process module (52b) are sequentially connected in series. A wafer (55) is conveyed between the load lock chamber and the first process module by the first conveyance mechanism and conveyed between the first process module and the second process module by the second conveyance mechanism.

### CROSS-REFERENCES TO RELATED APPLICATIONS

This application is a continuation application of International Application No. PCT/JP2007/071815, filed on Nov. 9, 2007, the entire contents of which are incorporated by reference herein.

### TECHNICAL FIELD

The present invention relates to a semiconductor manufacturing device and a manufacturing method and, in more detail, relates to an inline-type wafer conveyance device having a compact structure.

### BACKGROUND ART

There are several types of conventional semiconductor wafer conveyance devices and each of them has a big drawback. A conventional cluster-type wafer conveyance device has a structure in which a plurality of process modules is arranged radially around a robot chamber located in the center. Such a cluster-type wafer conveyance device requires a large footprint for installation. Further, each time processing in each process module is completed, a wafer is temporarily placed in a buffer part etc. and waits for the next processing, and therefore, the processing speed of the device as a whole is relatively slow. Further, in most cases, the maximum number of process modules in a cluster-type wafer conveyance device is normally limited to five or six for design reasons.

An inline-type wafer conveyance device has a higher processing speed compared to that of a cluster-type device. However, because of its rectilinear structure, it is hard to adapt the inline-type wafer conveyance device to the structure of a most recent semiconductor manufacturing facility. Further, in a conventional inline-type wafer conveyance device, when a wafer is conveyed in a vacuum environment in a semiconductor manufacturing process, there may be a case where particles occur at an unacceptable level due to the friction between the components of the waver conveyance device.

A plan view of a conventional inline-type wafer conveyance device is shown in FIG. 1 (for example, refer to patent document 1). In a wafer conveyance device 10, each of process modules 13a to 13g is arranged adjacent to each other and connected in an inline manner. Each process module is separated by a gate valve (not shown schematically). A wafer is conveyed from a load chamber 14 to the first process module 13a by a robot 12 within a robot chamber 11 and is processed sequentially in each process module. The processed wafer is conveyed from the last process module 13g to an unload chamber 15 by the robot 12. Extra robots to convey a wafer or robot chambers are not necessary, and therefore, a footprint required in the wafer conveyance device 10 is comparatively small.

A partial section view of the inline-type wafer conveyance device 10 shown in FIG. 1 is shown in FIG. 2. A wafer 21 is mounted on a carrier 23 and conveyed from a certain process module to the next process module. In each process module, the wafer 21 is lifted from the carrier 23 by a lift base 26 and processed, and then is mounted on the carrier 23 again and conveyed to the next process module. The carrier 23 is moved by means of a transfer mechanism, such as a roller 25. When the wafer 21 is conveyed to the next neighboring process module, a gate valve 24 is opened and thus the neighboring process modules are brought into a state where they are not hermetically sealed from each other. The wafer 21 having been subjected to processing in a certain process module waits until the next process module becomes empty.

A plan view of another conventional inline-type wafer conveyance device 30 is shown in FIG. 3 (for example, refer to patent document 2). The wafer conveyance device 30 comprises two front opening unified pods (FOUP) 31a and 31b. For example, the FOUP 31a has two load chambers 32a and 32b each having a cassette for storing an unprocessed wafer and the FOUP 31b has two unload chambers 33a and 33b each having a cassette for storing a processed wafer. The wafer conveyance device 30 further comprises buffer chambers 36a to 36d for temporarily placing a wafer during its conveyance. At the time of processing, a wafer is conveyed from a cassette within the load chamber 32a or 32b to the first buffer chamber 36a by a robot 35a within a robot chamber 34a. As shown schematically, the wafer conveyance device 30 comprises robot chambers 38a to 38c between the buffer chambers. Between each buffer chamber and its neighboring robot chamber, and between each robot chamber and its neighboring process module, a gate valve 39 is provided as shown schematically. A wafer once placed in the buffer chamber 36a is conveyed to a first process module 37a by a robot within the robot chamber 38a and processed therein. Subsequently, the wafer is conveyed to a second process module 37b again by the robot within the robot chamber 38a and processed therein. The wafer having been subjected to the processing in the second process module 37b is placed in the second buffer chamber 36b by the robot within the robot chamber 38a. Further, the wafer is conveyed from the buffer chamber 36b to a third process module 37c by the robot within the second robot chamber 38b. After that, the wafer is similarly moved from the process module 37c to a process module 37f sequentially and processed therein. The wafer having been subjected to the processing in all of the process modules is once placed in the buffer chamber 36d and then stored in the cassette within the unload chamber 33a or 33b of the FOUP 31b by a robot 35b within a robot chamber 34b. The wafer conveyance device 30 has an advantage that the number of the process modules can be increased flexibly as needed.

A plan view of a conventional cluster-type wafer conveyance device is shown in FIG. 4 (for example, refer to patent document 3). A wafer conveyance device 40 comprises an inlet module 45a and an outlet module 45b through which a wafer 46 is carried in from and carried out to outside, conveyance chambers 42a and 42b for conveying a wafer to process modules 41b, 41c, 41f and 41g, and conveyance robots 43a and 43b provided within the conveyance chambers 42a and 42b. A main controller 47 is communicated with each process module controller P, the inlet module 45a and the outlet module 45b, and an operator control panel via a standard communication bus 48. The wafer 46 not processed yet within the inlet module 45a is once placed on an aligner 44 by the conveyance robot 43a within the conveyance chamber 42a and its orientation is adjusted on the aligner 44. Then, the wafer on the aligner 44 is conveyed to, for example, the process module 41b or 41c by the conveyance robot 43a or 43b and processed therein, and then returned onto the aligner 44 again. After such a task is repeated, the wafer having been subjected to the processing in the process modules 41b, 41c, 41f and 41g is returned to the outlet module 45b by the conveyance robot 43a.

[Patent document 1] United States Patent Application Publication No. 2006/0102078 Specification

[Patent document 2] U.S. Pat. No. 7,210,246 Specification

[Patent document 3] Japanese Publication of Patent Application No. HEI 1-500072

### SUMMARY OF THE INVENTION

It is required, however, for the inline-type wafer conveyance device 10 shown in FIG. 1 and FIG. 2 to comprise the mobile carrier 23 capable of holding a wafer to be processed within the wafer conveyance device 10 and a transfer mechanism, such as the roller 25, for moving the carrier 23. In this case, a problem arises that the structure of the wafer conveyance device 10 becomes complicated and the price becomes expensive. Further, the carrier 23 is moved on a transfer mechanism, such as the roller 25, and therefore, a problem arises that particles are likely to be generated due to friction between these components. If the particle that has been generated sticks to the wafer 21 conveyed within the wafer conveyance device 10, the quality of a film to be formed on the wafer is deteriorated.

The conventional inline-type wafer conveyance device 30 shown in FIG. 3 requires the buffer, chambers 36a to 36d for temporarily placing a wafer, and therefore, a problem arises that the degree of complication of the device is increased. Further, a footprint required by the wafer conveyance device 30 becomes larger due to the necessity of these buffer chambers. Furthermore, if an attempt is made to realize the wafer conveyance device 30 without using the buffer chambers 36a to 36d, it becomes necessary to directly deliver, for example, a wafer having been subjected to the processing in the second process module 37b from the robot chamber 38a to the next robot chamber 38b. That is, it becomes necessary to deliver a wafer between the robots. If such a structure is employed, a problem arises that the precision and reliability of the operation of the wafer conveyance device 30 are degraded.

The conventional cluster-type wafer conveyance device 40 has a structure in which the process modules are arranged radially with the conveyance chambers 42a and 42b located in the center as a center, and therefore, a problem arises that its footprint is large. Further, with the cluster-type wafer conveyance device 40, it is necessary to once place a wafer on the aligner 44 before conveying the wafer to each process module. The necessity of such an aligner causes the footprint of the whole device to further increase. Then, each time processing is completed, the wafer needs to be placed on the aligner 44, and therefore, a complicated conveying task is required.

In order to solve the conventional problems described above, an object of the present invention is to realize an inline-type wafer conveyance device capable of suppressing the generation of particles, obviating a complicated conveyance mechanism for delivering a wafer between robots etc., and having a simple configuration with a small footprint.

In order to achieve the above-mentioned object, an inline-type wafer conveyance device of the present invention has a structure in which a load lock chamber for carrying in and out a wafer, a first conveyance module having a first conveyance mechanism, a first process module, a second conveyance module having a second conveyance mechanism, and a second process module are sequentially connected in series. In this wafer conveyance device, a wafer is conveyed between the load lock chamber and the first process module by the first conveyance mechanism and conveyed between the first process module and the second process module by the second conveyance mechanism.

It may also be possible to configure the above-mentioned load lock chamber so as to comprise a load chamber for carrying in an unprocessed wafer from outside and an unload chamber for carrying out a processed wafer to outside.

According to the present invention, an inline-type wafer conveyance device is realized, which is capable of suppressing the generation of particles, obviates a complicated conveyance mechanism, and has a simple structure with a small footprint.

### BRIEF DESCRIPTION OF THE DRAWINGS

FIG. 1 is a plan view of a conventional inline-type wafer conveyance device.

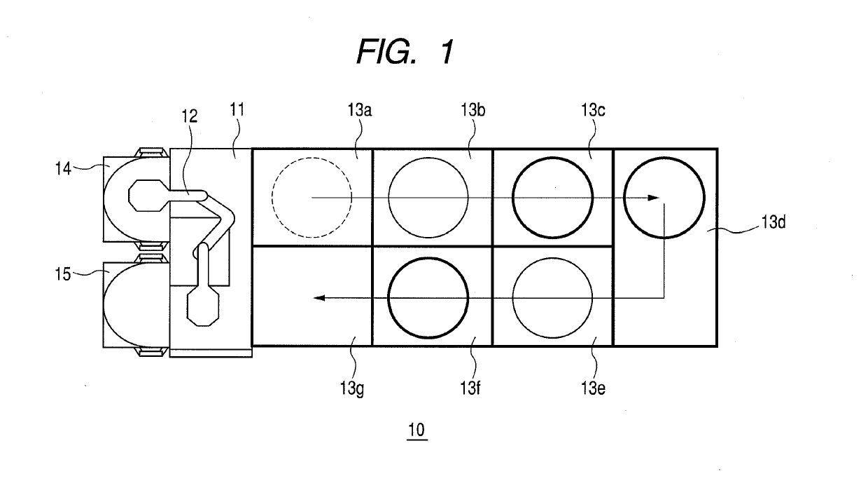

FIG. 2 is a partial section view of the conventional inline-type wafer conveyance device shown in FIG. 1.

FIG. 3 is a plan view of another conventional inline-type wafer conveyance device.

FIG. 4 is a plan view of a conventional cluster-type wafer conveyance device.

FIG. 5 is a plan view of an inline-type wafer conveyance device according to the present invention.

### REFERENCE SIGNS LIST

10 wafer conveyance device

11 robot chamber

12 robot

13a-13g process module

14 load chamber

15 unload chamber

21 wafer

23 carrier

24 gate valve

25 roller

26 lift base

30 wafer conveyance device

31a, 31b FOUP

32a, 32b load chamber

33a, 33b process module

34a, 34b robot chamber

35a, 35b robot

36a-36d buffer chamber

37a-37f process module

38a-38c robot chamber

39 gate valve

40 wafer conveyance device

41b, 41c, 41f, 41g process module

42a, 42b conveyance chamber

43a, 43b conveyance robot

44 aligner

45a inlet module

45b outlet module

46 wafer

47 main controller

48 standard communication bus

50 wafer conveyance device

51 load lock chamber

52a, 52b process module

53a, 53b conveyance chamber

54a, 54b conveyance mechanism

55 wafer

56 load chamber

57 unload chamber

58a-58d gate valve

### BEST MODES FOR CARRYING OUT THE INVENTION

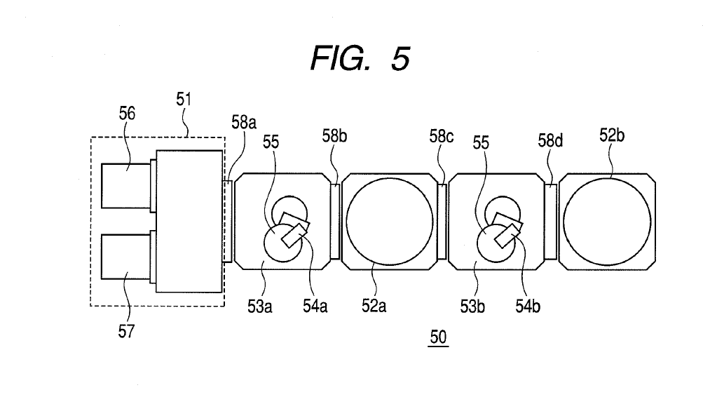

A plan view of an inline-type wafer conveyance device 50 according to the present invention is shown in FIG. 5. The wafer conveyance device 50 has an inline structure in which a load lock chamber 51, a first process module 52a and a second process module 52b are sequentially connected in series. Further, a first conveyance chamber 53a is provided between the load lock chamber 51 and the first process module 52a and a second conveyance chamber 53b is provided between the first process module 52a and the second process module 52b. As described above, the inline-type wafer conveyance device of the present invention has a characteristic structure in which the conveyance chambers and the process modules are alternately connected in series. A wafer 55 is conveyed between the load lock chamber 51 and the first process module 52a by a first conveyance mechanism 54a provided within the first conveyance chamber 53a. The wafer is also conveyed between the first process module 52a and the second process module 52b by a second conveyance mechanism 54b provided within the second conveyance chamber 53b. The first conveyance mechanism 54a and the second conveyance mechanism 54b are configured as a robot having an arm to move a wafer. It may also be possible to configure so that gate valves 58a to 58d are provided, respectively, between the load lock chamber 51 and the first conveyance chamber 53a, between the first conveyance chamber 53a and the first process module 52a, between the first process module 52a and the second conveyance chamber 53b, and between the second conveyance chamber 53b and the second process module 52b.

The load lock chamber 51 is configured to carry in an unprocessed wafer from outside (atmosphere side) and carry out a processed wafer to outside (atmosphere side) and includes an evacuation mechanism (not shown schematically). It may also be possible to configure the load lock chamber 51 so that a load chamber 56 configured to store an unprocessed waver carried in from outside (atmosphere side) and an unload chamber 57 configured to stack a processed wafer to be carried out to outside (atmosphere side) are provided separately as shown in FIG. 5.

An example of a process using the inline-type wafer conveyance device 50 in FIG. 5 will be described. First, an unprocessed wafer is carried into the load chamber 56 from outside (atmosphere side) and the inside of the load chamber 56 is evacuated into a vacuum state by an evacuation mechanism (not shown schematically). Next, the gate valve 58a between the first conveyance chamber 53a and the load lock chamber 51 and the gate valve 58b between the first conveyance chamber 53a and the first process module 52a are opened. The unprocessed wafer within the load lock chamber 51 is conveyed to the first process module 52a by the first conveyance mechanism 54a within the first conveyance chamber 53a, the gate valves that have been opened are closed and processing (for example, annealing) is performed on the wafer. Next, the gate valve 58c between the first process module 52a and the second conveyance chamber 53b and the gate valve 58d between the second conveyance chamber 53b and the second process module 52b are opened, the wafer within the first process module 52a is conveyed to the second process module 52b by the second conveyance mechanism 54b within the second conveyance chamber 53b, the gate valves that have been opened are closed and then processing (for example, sputter processing, etching processing, etc.) is performed on the wafer. After that, using the second conveyance mechanism 54b and the first conveyance mechanism 54a within the second conveyance chamber 53b and the first conveyance chamber 53a, the processed wafer is conveyed from the second process module 52b to the first process module 52a and further, from the first process module 52a to the unload chamber 57 within the load lock chamber 51 and carried out to outside. It may also be possible for the load lock chamber 51 to internally include a plurality of load/unload chambers (not shown schematically) configured to carry in an unprocessed wafer from outside (atmosphere side) and to carry out a processed wafer to outside (atmosphere side) separately. In this case, a wafer carried into the process module 52a from one load/unload chamber using a first end conveyance chamber 55a is sent to the same load/unload chamber or another load/unload chamber and carried out to outside when the processing in each process module is returned to the load lock chamber 51. In this case, the load chamber 56 and the unload chamber 57 are not necessary.

In order to obtain high throughput, it is necessary to make the processing time in each process module substantially the same. When the tact time required to process one wafer throughout the entire wafer conveyance device 50 is 36 seconds, the throughput of the wafer conveyance device 50 is 100 pph and 100 wafers can be processed in one hour. When the tact time is 12 seconds, the throughput is 300 pph and 300 wafers can be processed in one hour.

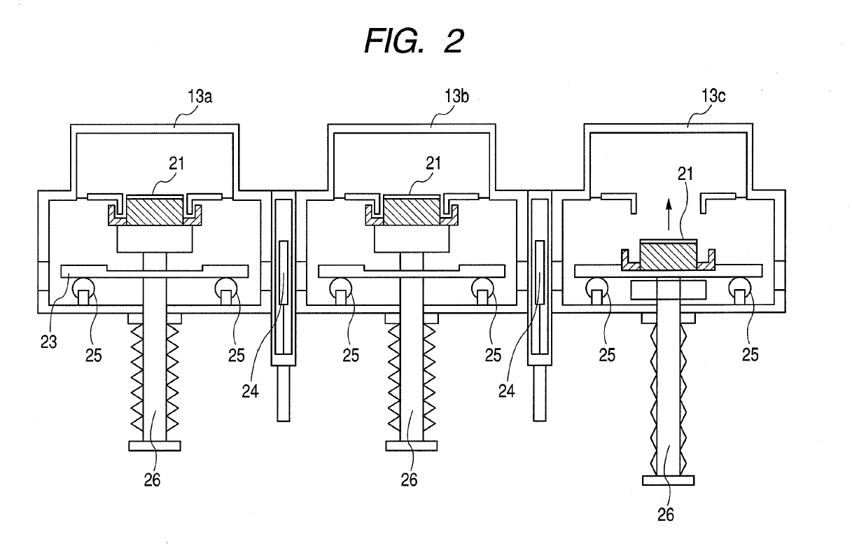

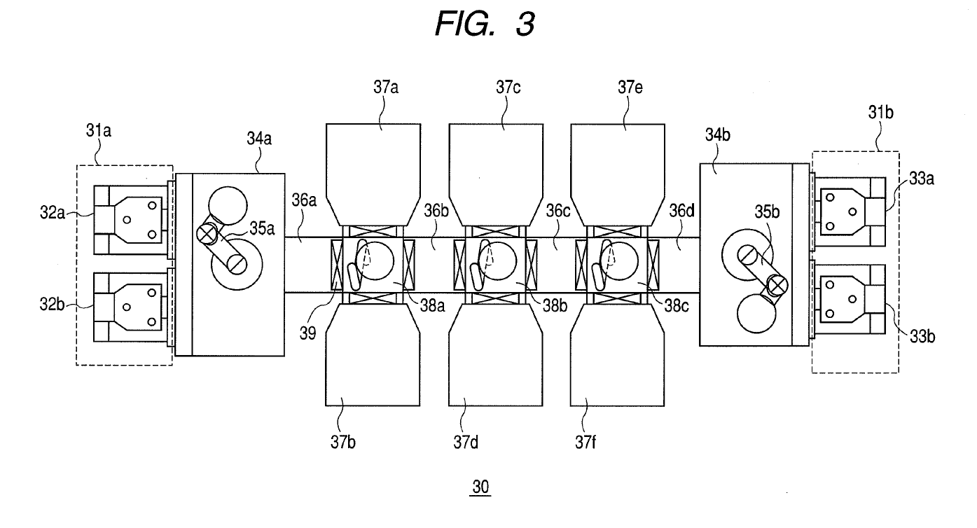

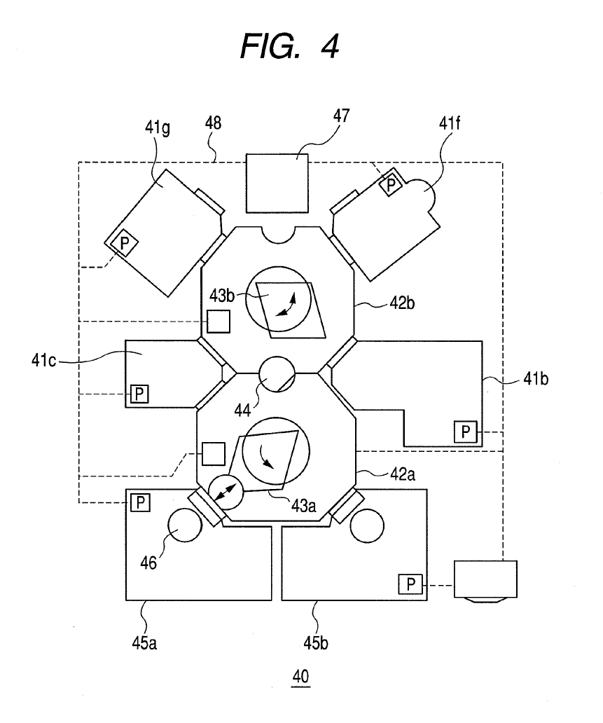

The inline-type wafer conveyance device of the present invention shown in FIG. 5 does not require a transfer mechanism, such as the carrier 23 and the roller 25 shown in FIG. 2. Because of this, particles are unlikely to be generated when a wafer is conveyed. Further, the wafer conveyance device has a simpler structure and a smaller footprint compared to the conveyance device that uses such a buffer chamber as shown in FIG. 3. Furthermore, it is not necessary for the robots to directly deliver a wafer between them, and therefore, a wafer conveyance device having high reliability can be realized. In addition, the wafer conveyance device has a very simple structure and a smaller footprint compared to the cluster-type conveyance device shown in FIG. 4. As described above, according to the present invention, it is possible to comprehensively solve the above-mentioned problems of the prior art.

The wafer conveyance device 50 shown as an example in the present embodiment comprises two conveyance chambers and two process modules, respectively. However, it will be obvious to a person with ordinary skill in the art that the wafer conveyance device of the present invention can be embodied flexibly by connecting in series a necessary number of conveyance chambers and process modules in accordance with a desired number of processes. Even when more conveyance chambers and more process modules are included, it is possible to realize the wafer conveyance device of the present invention as a simple structure with a small footprint.

1. An inline-type wafer conveyance device in which:
a load lock chamber for carrying in and out a wafer;
a first conveyance module having a first conveyance mechanism;
a first process module;
a second conveyance module having a second conveyance mechanism; and
a second process module are sequentially connected in series, wherein:
the first conveyance mechanism is adapted to convey a wafer between the load lock chamber and the first process module and the second conveyance mechanism is adapted to convey a wafer between the first process module and the second process module;
the load lock chamber comprises a load chamber for carrying in an unprocessed wafer from outside and an unload chamber for carrying out a processed wafer to outside; and
the first conveyance mechanism and the second conveyance mechanism convey the unprocessed wafer carried in from the load chamber to the first process module and the second process module, and carry out the processed wafer having been processed in the first process module and the second process module to the unload chamber.

2. (canceled)

3. A method of conveying a substrate comprising the steps of:
carrying an unprocessed wafer into a load chamber included in a load lock chamber and evacuating the inside of the load chamber into a vacuum state;
opening a first gate valve between a first conveyance chamber connected to the load lock chamber and the load lock chamber, and a second gate valve between the first conveyance chamber and a first process module connected to the first conveyance chamber, conveying an unprocessed wafer within the load lock chamber to the first process module using a first conveyance mechanism within the first conveyance chamber, closing the first and second gate valves that have been opened, and performing first processing on the unprocessed wafer;
opening a third gate valve between the first process module and a second conveyance chamber connected to the first process module, and a fourth gate valve between the second conveyance chamber and a second process module connected to the second conveyance chamber, conveying the wafer having been subjected to the first processing within the first process module to the second process module using a second conveyance mechanism within the second conveyance chamber, closing the third and fourth gate valves that have been opened, and performing second processing on the wafer having been subjected to the first processing; and
conveying the processed wafer from the second process module to the first process module using the second conveyance mechanism, and further conveying the processed wafer from the first process module to the unload chamber within the load lock chamber and carrying out the processed wafer to outside using the first conveyance mechanism.

4. A method of conveying a substrate according to claim 3, wherein processing time in the first and second process modules is the same.
